(19) United States
(12) Patent Application Publication
(10) Pub. No.: US 2018/0316343 A1
(43) Pub. Date: Nov. 1, 2018

(54) Transistor Switch

(71) Applicant: QUALCOMM Incorporated, San Diego, CA (US)

(72) Inventor: Sinan Goktepeli, San Diego, CA (US)

(21) Appl. No.: 15/582,080

(22) Filed: Apr. 28, 2017

(51) Int. Cl. H03K 17/16; H04B 1/44

(52) U.S. Cl. CPC H03K 17/168; H04B 1/44

(57) ABSTRACT

Various aspects of this disclosure describe configuring and operating a transistor switch. Examples include a biasing circuit that contains a pair of diodes and a pair of resistors. The resistors may be placed in parallel by forward-biasing the pair of diodes. When the transistor is disabled (e.g., switch is open), gate-induced-drain-leakage (GIDL) current from the transistor, when flowing, may be split between each of the resistors to inhibit a voltage drop on the gate of the transistor, which may reduce harmonic distortion and/or increase the breakdown voltage of the transistor. The resistor values can be selected to ensure that the gate voltage of the transistor stays approximately equal to a negative bias voltage.

### BACKGROUND

### Field of the Disclosure

The present disclosure relates to a transistor configured as a switch, and improvements thereto.

### Description of Related Art

Switches are used throughout computing devices, such as for separating transmit and receive signals that may share an antenna in a mobile phone, as building blocks to construct multiplexors, and generally to route data appropriately within the computing device. Switches can be implemented using transistors or logic gates.

### SUMMARY

This Summary is provided to introduce a selection of concepts in a simplified form that are further described below in the Detailed Description. This Summary is not intended to identify key features or essential features of the claimed subject matter.

In some aspects, a switch comprises a transistor, a first diode, a second diode, a first resistor, and a second resistor. The first diode has an anode connected to a body of the transistor and a cathode connected to a gate of the transistor. The first resistor is connected to the gate of the transistor and to a voltage. The second resistor is connected to the body of the transistor and to an anode of a second diode. The second diode has a cathode connected to the voltage.

In other aspects, a method of operating a switch comprises applying a first voltage to a gate of a transistor through a first resistor to disable the transistor in an off state. The method also includes placing a second resistor in parallel with the first resistor responsive to applying the first voltage. The method also includes causing GIDL current to flow through the second resistor. The method also includes applying a second voltage to the gate of the transistor to enable the transistor in an on state. The method also includes removing the second resistor from being in parallel with the first resistor responsive to applying the second voltage.

In still other aspects, a device comprises means for applying a first voltage to a gate of a transistor through a first resistor to disable the transistor in an off state. The device also comprises means for placing a second resistor in parallel with the first resistor responsive to applying the first voltage. The device also comprises means for causing GIDL current to flow through the second resistor.

In yet other aspects, a system comprises a transistor and a first resistor having a first terminal connected to a gate of the transistor and a second terminal coupled to a voltage input. The system also comprises a second resistor having a first terminal connected to a body of the transistor and a second terminal coupled to the voltage input. The system also comprises a pair of diodes configured to selectively place the first resistor and the second resistor in parallel.

The foregoing is a summary and thus contains, by necessity, simplifications, generalizations and omissions of detail; consequently, those skilled in the art will appreciate that the summary is illustrative only and does not purport to be limiting in any way. Other aspects, inventive features, and advantages of the devices and/or processes described herein, as defined solely by the claims, will become apparent in the non-limiting detailed description set forth herein.

### BRIEF DESCRIPTION OF DRAWINGS

The detailed description references the accompanying figures. In the figures, the left-most digit(s) of a reference number identifies the figure in which the reference number first appears. The use of the same reference numbers in different instances in the description and the figures may indicate similar or identical items.

FIG. 1 illustrates an example operating environment in accordance with one or more aspects of the disclosure.

FIG. 2 illustrates a block diagram of a design of a wireless communication device in which aspects of the disclosure may be implemented.

FIG. 3 illustrates prior art switch circuitry.

FIG. 4 illustrates example switch performance data in accordance with one or more aspects of the disclosure.

FIG. 5 illustrates example switch circuitry in accordance with one or more aspects of the disclosure.

FIG. 6 illustrates example switch performance data in accordance with one or more aspects of the disclosure.

FIG. 7 illustrates an example method for configuring and operating a transistor switch in accordance with one or more aspects of the disclosure.

FIG. 8 illustrates an example device having components through which aspects of configuring and operating a transistor switch can be implemented in accordance with one or more aspects of the disclosure.

### DETAILED DESCRIPTION

Overview

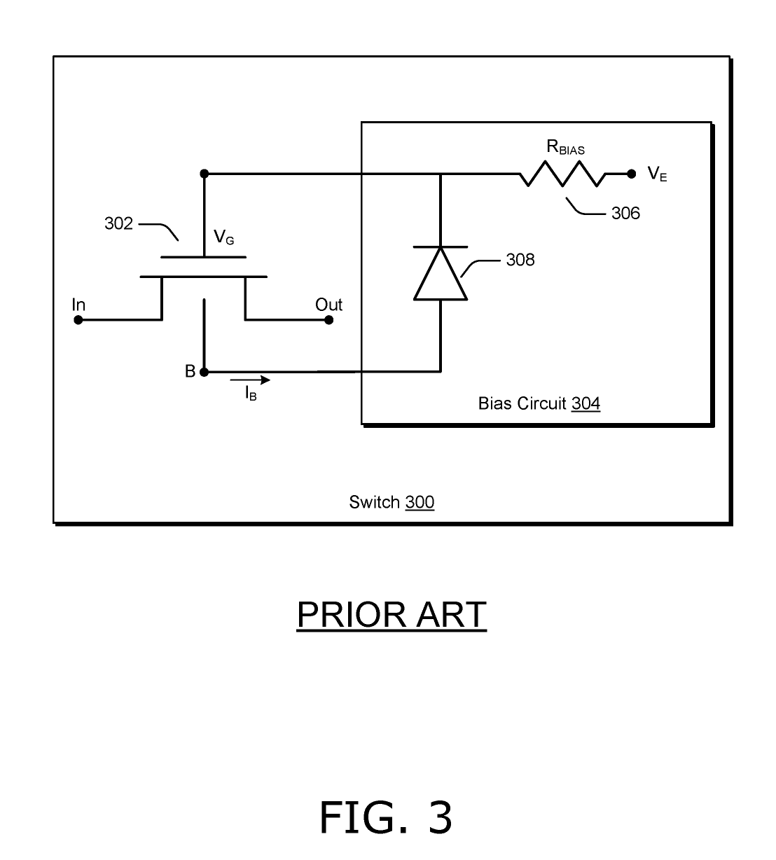

Switches are used ubiquitously throughout communications and computing devices. Transistors may be configured as switches and implemented in semiconductor devices to route data and select appropriate signals among a plurality of signals (e.g., such as in a multiplexor). For instance, transistor switches are often used as transmit/receive switches to separate transmitting and receiving radio frequency (RF) signals that may share an antenna in a cellular phone because of the speed and performance of a transistor switch. Transistor switches are oftentimes implemented with a diode connected from the body of the transistor to the gate of the transistor (see FIG. 3). This diode inhibits physical movement of the gate relative to the body, which affects harmonic distortion of the transistor. The gate of the transistor is supplied a voltage, such as through a bias resistor, to disable and enable the transistor, e.g., to turn the transistor off and on, respectively. When the gate is negatively biased to disable the transistor, gate-induced-drain-leakage (GIDL) current can flow from the body of the transistor through the diode and through the bias resistor, creating a voltage drop across the bias resistor that is proportional to the GIDL current. This voltage drop across the bias resistor causes the negatively biased gate of the transistor to drop in voltage, e.g. become less negative, which adversely affects harmonic distortion and breakdown voltage of the transistor. The inventor has determined that the amount of GIDL current increases exponentially as the power of the input signal to the transistor is increased, which increases harmonic distortion and decreases the breakdown voltage of the transistor—both undesirable results.

In contrast to bias circuits that negatively bias a transistor switch to disable the switch and create a significant voltage drop on the gate of the transistor, this disclosure describes a bias circuit configured to reduce the voltage drop on the gate of the transistor when the gate is negatively biased by routing GIDL current away from a bias resistor. The bias circuit uses a pair of diodes and a pair of resistors, instead of a single diode and a single resistor. When the transistor is disabled, the pair of diodes act to place the pair of resistors in parallel, so that the GIDL current is split between the bias resistor and a body resistor. By reducing the amount of GIDL current flowing through the bias resistor, the voltage drop across the bias resistor is reduced, so that the voltage drop at the negatively-biased gate is reduced, e.g., the negatively-biased gate is inhibited from becoming less negative. This improves harmonic distortion and retains a high breakdown voltage of the transistor.

In the following discussion, an example system including a bias circuit and transistor configured as a switch is described. Techniques or procedures that elements of the example system may implement, and a device on which elements of the example system may be embodied, are also described. Consequently, performance of the example procedures is not limited to the example system and the example system is not limited to performance of the example procedures. Any reference made with respect to the example system, or elements thereof, is by way of example only and is not intended to limit any of the aspects described herein.

Example Environment

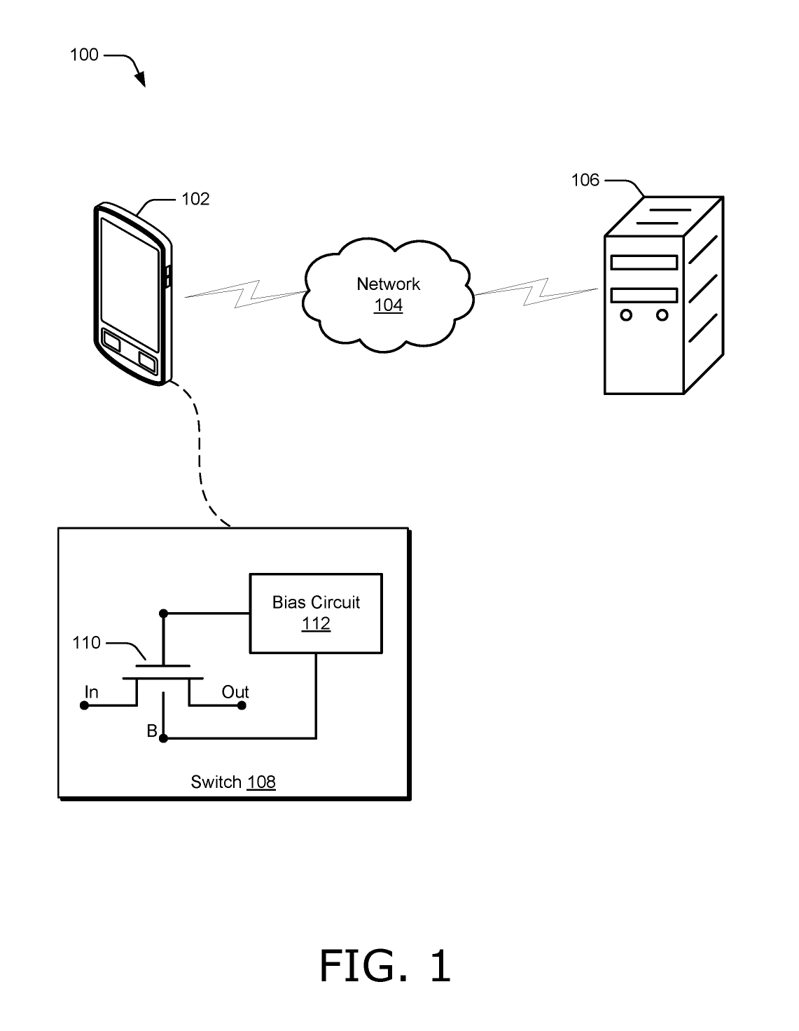

FIG. 1 illustrates example operating environment 100 in accordance with one or more aspects of the disclosure. Example environment 100 comprises user device 102 communicating via network 104 with computing device 106. User device 102 can be any suitable type of computing device, such as a client device, a desktop computer, a laptop computer, a mobile device (e.g., a handheld configuration such as a tablet or mobile phone), a tablet, a camera, a gaming device, a set-top box, a satellite receiver, a cable television receiver, an access point, a vehicle navigation system, and the like. Thus, user device 102 may range from full resource devices with substantial memory and processor resources (e.g., personal computers, game consoles) to a low-resource device with limited memory and/or processing resources (e.g., mobile devices). Additionally, although a single user device 102 is shown, the user device 102 may be representative of a plurality of different devices to perform operations “over the cloud”.

Though illustrated as coupled to network 104 in FIG. 1, user device 102 can also operate stand-alone, e.g., while not connected to a network. For example, a user may disconnect user device 102 from network 104 by any suitable fashion, such as selection of an option in a user interface to disable transceiver operation in user device 102, and place user device 102 in an “airplane mode”.

Network 104 may comprise a variety of networks, including the Internet, an intranet, local area network (LAN), wide area network (WAN), personal area network (PAN), body area network (BAN), cellular networks, terrestrial networks, satellite networks, combinations of networks, and the like, and as such may be wired and/or wireless.

Computing device 106 is a device that is communicatively coupled via network 104 to user device 102. In one example, computing device 106 is a server configured to provide data and services to user device 102 responsive to receiving a request from user device 102. Some examples of services include, but are not limited to, a photo editing and storage service, a web development and management service, a collaboration service, a social networking service, a messaging service, an advertisement service, and so forth. In another example, computing device 106 is a client device, and computing device 106 and user device 102 communicate in a peer-to-peer (P2P) fashion. In another example, computing device 106 is a base station and user device 102 communicates with the computing device 106 using a cellular standard.

User device 102 contains one or more switches an example of which is switch 108, comprising transistor 110 and bias circuit 112. Transistor 110 is configured as a switch, and receives an input signal on an input terminal of transistor 110 (labeled “In”), and supplies an output signal on an output terminal of transistor 110 (labeled “Out”). In one example, the input terminal is a source of transistor 110, and the output terminal is a drain of transistor 110. In another example, the input terminal is a drain of transistor 110, and the output terminal is a source of transistor 110. A gate of transistor 110 is connected to bias circuit 112. The body of transistor 110 (labeled “B”) is the bulk of semiconductor material in which the gate, source, and drain lie, and is also connected to bias circuit 112.

Bias circuit 112 sets a bias voltage on the gate of transistor 110 to enable or disable transistor 110 (e.g., turn it on or off to open or close the switch, respectively). For example, bias circuit 112 sets a voltage on the gate of transistor 110 sufficiently large to cause the input signal on the input terminal of transistor 110 to be transferred to the output terminal of transistor 110. A sufficiently large voltage may be V_{DD}, where V_{DD} is a positive supply voltage, such as 1.8 volts. In this case, transistor 110 is said to be enabled, (e.g., corresponding to an on state). Conversely, bias circuit 112 sets a voltage on the gate of transistor 110 sufficiently small to inhibit the input signal on the input terminal of transistor 110 from being transferred to the output terminal of transistor 110. A sufficiently small voltage may be a negative voltage, such as the negative of V_{DD}, e.g., −1.8 volts. In this case, transistor 110 is said to be disabled, (e.g., corresponding to an off state).

Transistor 110 is illustrated for convenience as a field-effect transistor (FET). However, transistor 110 can be any suitable type of transistor, such as, by way of example and not limitation, a metal-oxide-semiconductor field-effect transistor (MOSFET), a junction field-effect transistor (JFET), a metal-semiconductor field-effect transistor (MESFET), a bipolar junction transistor (BJT), and the like, can operate in any suitable type of mode, such as depletion mode or enhancement mode, and can be n-channel or p-channel.

Switch 108 is illustrated as a single switch. In implementations, switch 108 comprises a plurality of transistors and bias circuits, each similar to transistor 110 and bias circuit 112, respectively, and therefore represents a plurality of switches configured in any suitable fashion. For example, switch 108 can represent a plurality of switches configured to comprise a multiplexor or demultiplexor, capable of providing parallel-to-serial conversion, or serial-to-parallel conversion, respectively. In addition, switch 108 is illustrated as being a part of user device 102 for simplicity, and can be incorporated in any suitable device, such as user device 102, components of network 104, and/or computing device 106. In implementations, switch 108 can be a part of a stand-alone device that is not connected to a network, such as user device 102 when it is disconnected from network 104.

Switch 108 can be used to facilitate numerous functions in user device 102. By way of example and not limitation, switch 108 is an RF transmit/receive switch for selecting transmit and receive signals that share an antenna in user device 102, such as a transmit signal to be transmitted by a transmitter, or a received signal to be received by a receiver. In another example, switch 108 is used to construct a multiplexor or demultiplexor and route sub-channel data in a multiple-input and multiple-output transceiver used to communicate orthogonal frequency division multiplexed (OFDM) signals. In still another example, switch 108 is used to select between outputs of filter stages in a multi-stage filter, such as a multi-stage filter that processes baseband signals in a transceiver of a cellular phone. Therefore, example environment 100 is illustrative of example implementations of switch 108 and does not purport to be limiting in any way.

Having considered a discussion of example environment 100, consider now a discussion of a block diagram of a design of a wireless communication device in which aspects of the disclosure may be implemented.

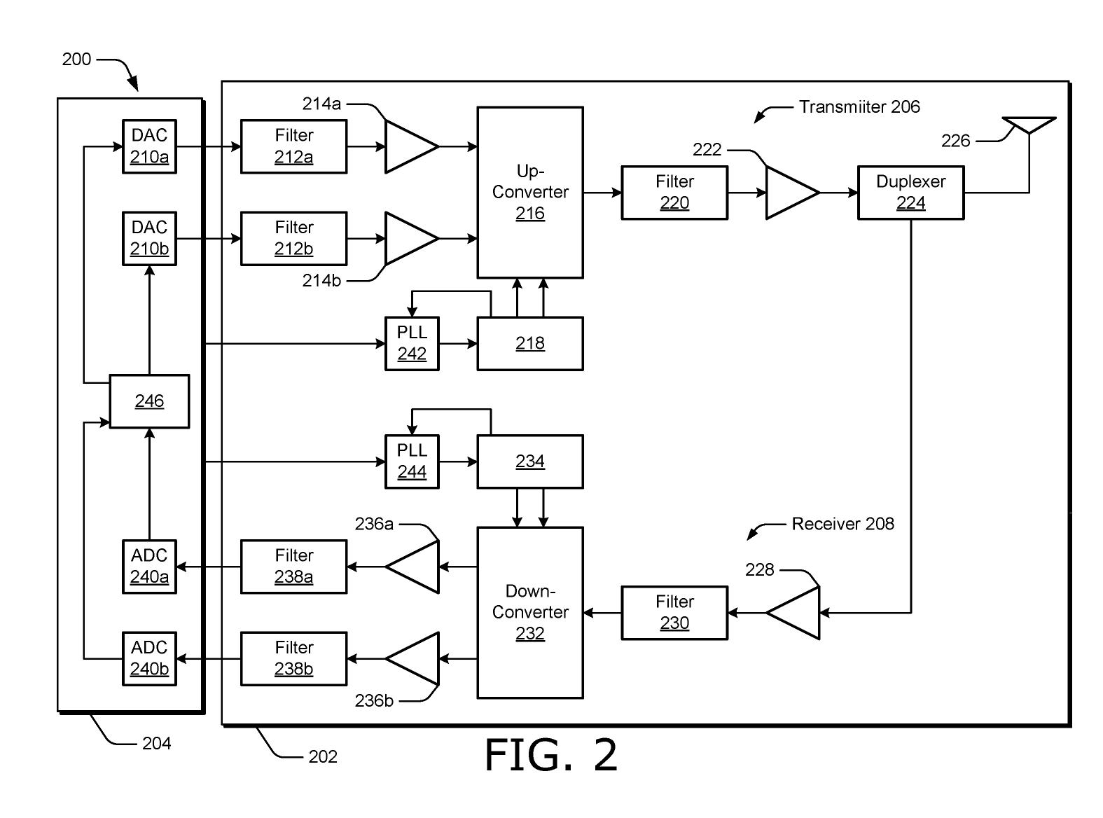

FIG. 2 illustrates a block diagram of a design of a wireless communication device 200 in which aspects of the present disclosure may be implemented. FIG. 2 shows an example transceiver design. In general, the conditioning of the signals in a transmitter and a receiver may be performed by one or more stages of amplifier, filter, upconverter, downconverter, etc. These circuit blocks may be arranged differently from the configuration shown in FIG. 2. Furthermore, other circuit blocks not shown in FIG. 2 may also be used to condition the signals in the transmitter and receiver. Some circuit blocks in FIG. 2 may also be omitted.

In the design shown in FIG. 2, wireless device 200 includes a transceiver 202 and a data processor 204. The data processor 204 may include a memory (not shown) to store data and program codes. Transceiver 202 includes a transmitter 206 and a receiver 208 that support bi-directional communication. In general, wireless device 200 may include any number of transmitters and any number of receivers for any number of communication systems and frequency bands. All or a portion of transceiver 202 may be implemented on one or more analog integrated circuits (ICs), RF ICs (RFICs), mixed-signal ICs, etc. The term transceiver is used herein to functionally describe elements of the device 200. Those of skill in the art will understand that certain of the elements illustrated in transceiver 202 may be included in a transceiver chip, module, or circuit, while other elements of the transceiver 202 may be implemented separately in a radio frequency front end and/or as discrete components or in a separate module, for example.

A transmitter or a receiver may be implemented with a super-heterodyne architecture or a direct-conversion architecture. In the super-heterodyne architecture, a signal is frequency converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the design shown in FIG. 2, transmitter 206 and receiver 208 are implemented with the direct-conversion architecture.

In the transmit path, data processor 204 processes data to be transmitted and provides I and Q analog output signals to transmitter 206. In the exemplary embodiment shown, the data processor 204 includes digital-to-analog-converters (DAC's) 210a and 210b for converting digital signals generated by the data processor 204 into the I and Q analog output signals, e.g., I and Q output currents, for further processing. In other embodiments, signals may be output from the data processor 204 to the transceiver 202 digitally, and one or more DAC's may be implemented in the transceiver 202 to convert the output signals to analog signals.

Within transmitter 206, lowpass filters 212a and 212b filter the I and Q analog output signals, respectively, to remove undesired images caused by the prior digital-to-analog conversion. Amplifiers 214a and 214b amplify the signals from lowpass filters 212a and 212b, respectively, and provide I and Q baseband signals. An upconverter 216 upconverts the I and Q baseband signals with I and Q transmit (TX) local oscillating (LO) signals from a TX LO signal generator 218 and provides an upconverted signal. A filter 220 filters the upconverted signal to remove undesired images caused by the frequency upconversion as well as noise in a receive frequency band. A power amplifier (PA) 222 amplifies the signal from filter 220 to obtain the desired output power level and provides a transmit RF signal. The transmit RF signal is routed through a duplexer 224 (e.g., a switch, such as the switch 108 in FIG. 1) and transmitted via an antenna 226. While not illustrated herein, the switch 108 may be implemented in other locations within the device 200 and/or may be used to implement various elements illustrated in FIG. 2. In some embodiments, the switch 108 is used to implement any number of high power switches.

In the receive path, antenna 226 receives signals transmitted (e.g., by base stations, other wireless communication devices, etc.) and provides a received RF signal, which is routed through duplexer 224 and provided to a low noise amplifier (LNA) 228. The received RF signal is amplified by LNA 228 and filtered by a filter 230 to obtain a desirable RF input signal. A downconverter 232 downconverts the RF input signal with I and Q receive (RX) LO signals from an RX LO signal generator 234 and provides I and Q baseband signals. The I and Q baseband signals are amplified by amplifiers 236a and 236b and further filtered by lowpass filters 238a and 238b to obtain I and Q analog input signals, which are provided to data processor 204. In the exemplary embodiment shown, the data processor 204 includes analog-to-digital-converters (ADC's) 240a and 240b for converting the analog input signals into digital signals to be further processed by the data processor 204. In other embodiments, signals may be output from the transceiver 202 to the data processor 204 digitally, and one or more ADC's may be implemented in the transceiver 202 to convert signals to digital for outputting.

TX LO signal generator 218 generates the I and Q TX LO signals used for frequency upconversion. RX LO signal generator 234 generates the I and Q RX LO signals used for frequency downconversion. Each LO signal is a periodic signal with a particular fundamental frequency. A phase-locked loop (PLL) 242 receives timing information from data processor 204 and generates a control signal used to adjust the frequency and/or phase of the TX LO signals from LO signal generator 218. Similarly, a PLL 244 receives timing information from data processor 204 and generates a control signal used to adjust the frequency and/or phase of the RX LO signals from LO signal generator 234.

The data processor 204 further includes a baseband processing module 246 configured to process RX data from the ADC's 240a, 240b, and further to process TX data to the DAC's 210a, 210b.

In some embodiments, a plurality of antennas (not illustrated) are implemented (e.g., instead of or in addition to the antenna 226). These antennas may be used with shared or separate transceiver chains (concurrently or at separate times or in separate modes), for beamforming, for carrier aggregation, for MIMO, and/or for diversity, among other purposes. The antennas may be coupled through one or more duplexors, diplexors, or mulitplexors, and/or may be separately coupled to one or more receive and/or transmit chains. They may couple to transmit and/or receive circuitry as described above and in additional ways which will be understood by one of skill in the art.

Having considered a discussion of example environment 100 and device 200, consider now a discussion of example switch circuitry.

Example Switch Circuitry

FIG. 3 illustrates a prior art switch 300. Switch 300 comprises a transistor 302 and a bias circuit 304. Bias circuit 304 acts to apply a voltage on the gate of transistor 302 to enable or disable transistor 302.

Bias circuit 304 includes bias resistor 306 (labeled R_{BIAS}) and diode 308. Resistor 306 is a biasing resistor that is connected to a voltage, V_{E}, and to a gate of transistor 302. The voltage can be set sufficiently positive to enable transistor 302, such as to V_{DD}, e.g., +1.8 volts, or sufficiently negative to disable transistor 302, such as to the negative of V_{DD}, e.g., −1.8 volts.

Diode 308 has an anode connected to the body of transistor 302 and a cathode connected to a gate of transistor 302. Diode 308 may anchor the body of transistor 302 to the gate of transistor 302 so as to inhibit physical movement of the gate of transistor 302 relative to the body of transistor 302. Such movement is known to cause harmonic distortion measurable at the output of transistor 302. When the gate of transistor 302 is negatively biased to disable transistor 302 (e.g., open the switch), GIDL current can flow from the body of transistor 302 through diode 308 and through resistor 306. In FIG. 3, the GIDL current is denoted by current I_{B}. GIDL current is caused due to a high potential difference between the gate and the drain of transistor 302.

When flowing, GIDL current in switch 300 causes the negatively-biased gate of transistor 302 to drop in voltage, e.g. become less negative. For example, the negatively-biased gate voltage, V_{G}, in switch 300 can be written as

V_{G}=V_{E}−I_{B}·R_{BIAS}

where the product of the GIDL current and the bias resistor (I_{B})·R_{BIAS}) represents the voltage drop across resistor 306 due to the GIDL current. Because all the GIDL current flows through resistor 306 in switch 300, the voltage drop across resistor 306, and hence the drop in voltage of the negatively-biased gate of transistor 302, are proportional to the GIDL current. When the negatively-biased gate of transistor 302 suffers a voltage drop due to GIDL current flowing through resistor 306, harmonic distortion of transistor 302 is increased. For example, when a tone is provided at the input terminal of transistor 302, harmonics of the input tone are increased at the output terminal of transistor 302, such as second and third order harmonics, despite the switch being open. GIDL current increases exponentially as the power of the input signal is increased.

Furthermore, the breakdown voltage, V_{BD}, of transistor 302 (e.g., the drain-to-source voltage that causes the transistor to enter a breakdown region where drain current drastically increases) is roughly a linear function of the magnitude of the gate voltage of the transistor. Hence, when GIDL current flows in switch 300, not only does harmonic distortion increase due to the voltage drop at the negatively-biased gate of transistor 302, but also the breakdown voltage is decreased, which limits the operating range of transistor 302.

Having considered a discussion of prior art switch circuitry 300, consider now a discussion of example switch performance data.

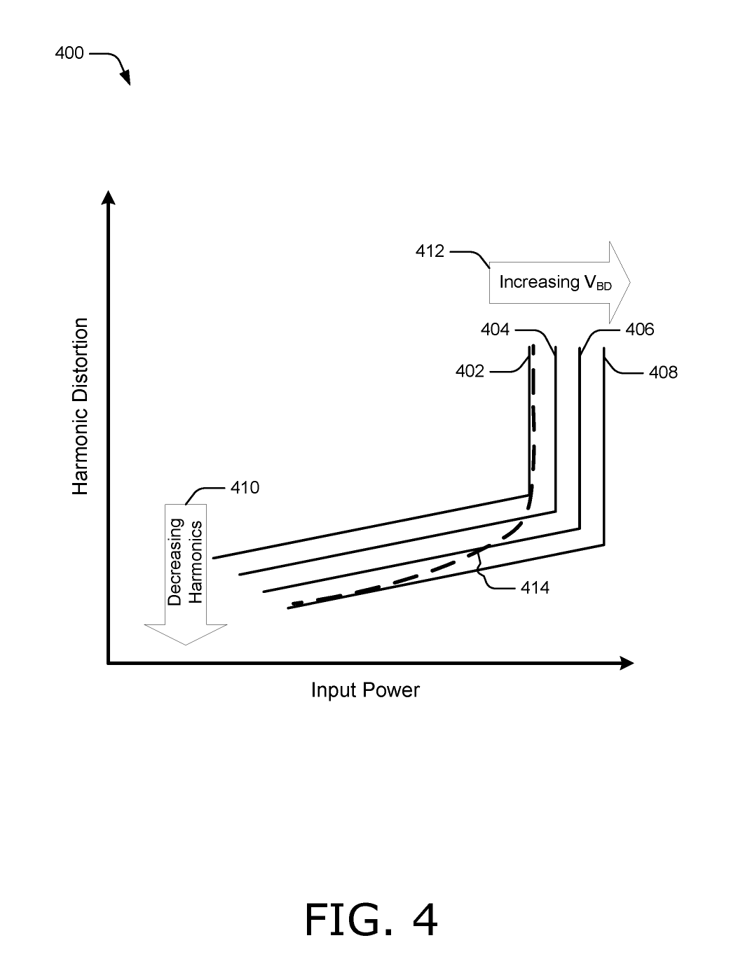

FIG. 4 illustrates example switch performance data 400 in accordance with one or more aspects of the disclosure. Example switch performance data 400 plots harmonic distortion measured at a switch transistor output, such as the output terminal of transistor 302, versus input power of an input signal, such as applied to the input terminal of transistor 302. In an example, the input signal is a tone, and the harmonic distortion is a measure of the power of a second or third harmonic of the input signal.

Example switch performance data 400 includes a family of four curves, 402, 404, 406, and 408. Each of curves 402, 404, 406, and 408 correspond to performance of a transistor, such as transistor 302, at a different gate voltage when the gate of the transistor is negatively biased to disable the transistor (e.g., open the switch). The curves 402, 404, 406, and 408 are in an order according to the different gate voltages. For example, curve 408 corresponds to a gate voltage that is more negative than the gate voltage corresponding to curve 406; curve 406 corresponds to a gate voltage that is more negative than the gate voltage corresponding to curve 404; and curve 404 corresponds to a gate voltage that is more negative than the gate voltage corresponding to curve 402. Note that curves 402, 404, 406, and 408 correspond to performance of transistor 302 alone, e.g., in the absence of a bias circuit, such as bias circuit 304.

Indicator 410 shows the direction on the graph corresponding to decreasing harmonic distortion. Thus, curve 408 has the lowest harmonic distortion among the four curves 402, 404, 406, and 408, while curve 402 has the highest harmonic distortion among the four curves 402, 404, 406, and 408. Accordingly, harmonic distortion decreases as the gate voltage of transistor 302 is made more negative.

Indicator 412 shows the direction on the graph corresponding to increasing breakdown voltage of the transistor, such a transistor 302. Thus, curve 408 has the highest breakdown voltage among the four curves 402, 404, 406, and 408, while curve 402 has the lowest breakdown voltage among the four curves 402, 404, 406, and 408. Accordingly, breakdown voltage increases as the gate voltage of transistor 302 is made more negative.

Indicators 410 and 412 illustrate that a drop in gate voltage of a negatively-biased transistor adversely affects harmonic distortion and breakdown voltage.

Curve 414, indicated as a dashed line, shows performance of prior art switch 300, including bias circuit 304 as illustrated in FIG. 3, at a constant value of V_{E} to negatively bias the gate of transistor 302. Because of the addition of bias circuit 304, curve 414 does not follow the family of four curves 402, 404, 406, and 408. Rather, curve 414 indicates that as the input power is increased, harmonic distortion prematurely increases, and the breakdown voltage of the transistor is decreased, even at a constant control voltage V_{E}. For example, the shape of curve 414 resembles more of an arc than the “hockey-stick” shape of curves 402, 404, 406, and 408. The GIDL current increases exponentially as the input power is increased, accounting for the distortion in the shape of curve 414 compared to curves 402, 404, 406, and 408.

The inventor has determined that the performance described by curve 414 is the result of GIDL current flowing through the bias resistor 306, and consequently causing a voltage drop in the negatively-biased gate voltage of transistor 302, as described with reference to FIG. 3. This behavior is not well understood by the skilled artisan, and is easily misunderstood to be a result of transistor punch-through effect (where the source-to-drain electric field penetrates the transistor body), or simply not recognized as a problem. Instead, the inventor has recognized that the performance described by curve 414 is a problem associated with prior art switch 300, specifically bias circuit 304, where others have not recognized and/or understood the problem.

Having considered a discussion of example switch performance data 400, consider now a discussion of example switch circuitry.

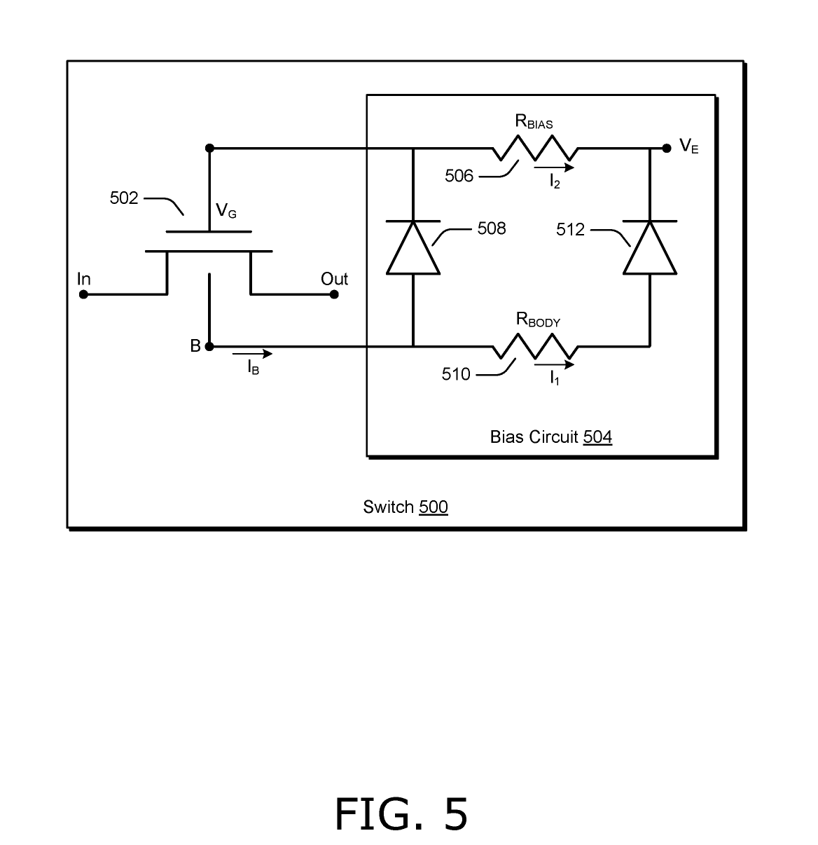

FIG. 5 illustrates example switch 500 in accordance with one or more aspects of the disclosure. Example switch 500 includes transistor 502 and bias circuit 504, and may comprise an implementation or an embodiment of the switch 108 illustrated in FIG. 1. Bias circuit 504 includes resistor 506 and diode 508. However, unlike bias circuit 304 of FIG. 3, bias circuit 504 in FIG. 5 also includes body resistor 510 (labeled R_{BODY}) and diode 512. Body resistor 510 is connected to the body of transistor 502 and an anode of diode 512. Diode 512 has a cathode connected to the voltage, V_{E}. Thus, bias circuit 504 includes a pair of diodes and a pair of resistors.

When the voltage, V_{E}, is a negative voltage used to disable transistor 502 (e.g., place the transistor in an off state so the switch is open), the pair of diodes 508 and 512 are forward-biased, and act to place the pair of resistors 506 and 510 in parallel. For example, since the diodes are forward-biased, they appear as short circuits. Because the pair of resistors 506 and 510 are placed in parallel, GIDL current, when flowing, flows from the body of transistor 502 through bias resistor 506 and body resistor 510. The GIDL current is split between the pair of resistors, and the amount of GIDL current that flows through each resistor is determined based on the relative size of bias resistor 506 compared to body resistor 510. For instance, the GIDL current is represented as I_{B}=I₁+I₂, where I₁ flows through body resistor 510 and I₂ flows through bias resistor 506. The amount of GIDL current that flows through bias resistor 506 is

$${I}_{2} = {I}_{B} \cdot \frac{{R}_{BODY}}{{R}_{BODY} + {R}_{BIAS}} ,$$

which is less than the total GIDL current, I_{B}. Consequently, the voltage drop on the negatively-biased gate of transistor 502 is reduced, compared to all the GIDL current flowing through bias resistor 506, as is the case for bias circuit 304 in FIG. 3. Specifically, the voltage on the gate of transistor 502 is

$${V}_{G} = {V}_{E} - {I}_{B} \cdot \frac{{R}_{BODY}}{{R}_{BODY} + {R}_{BIAS}} \cdot {R}_{BIAS}$$

The product of the GIDL current and parallel resistance

$$( {I}_{B} \cdot \frac{{R}_{BODY}}{{R}_{BODY} + {R}_{BIAS}} \cdot {R}_{BIAS} )$$

represents the voltage drop across resistor 506 due to the portion of the GIDL current flowing through resistor 506. Thus, body resistor 510 acts to inhibit the voltage on the gate of transistor 502 from becoming less negative by preventing all of the GIDL current from flowing through resistor 506. For instance, the body resistor 510 causes a voltage on the gate of transistor 502 to become more negative when the transistor is in an off state compared to when the body resistor 510 is disconnected from the switch 500. Because the voltage on the negatively-biased gate of transistor 502 is not dropped so significantly, harmonic distortion is reduced and the breakdown voltage of transistor 502 is increased.

The voltage on the gate of transistor 502 can be maintained by proper selection of resistors 506 and 510. For instance, by selecting the resistance value of body resistor 510 to be less the resistance value of bias resistor 506, more of the GIDL current flows through body resistor 510 than flows through bias resistor 506, which inhibits the increasing of harmonic distortion and the decreasing of breakdown voltage of transistor 502. In one example, the resistance value of body resistor 510 is selected to be nominally (e.g., within device tolerances when measured) half the resistance value of bias resistor 506. In this example, approximately one third of the GIDL current flows through bias resistor 506, while approximately two-thirds of the GIDL current flows through body resistor 510. In this example, the voltage drop across bias resistor 506, and thus the voltage drop at the gate of transistor 502, is therefore reduced by approximately 66.67% compared to all of the GIDL current flowing through bias resistor 506.

The GIDL current that flows through the second resistor causes a higher breakdown voltage of the transistor compared to when no GIDL flows through the second resistor. Moreover, GIDL current that flows through the second resistor causes a lower harmonic distortion of the transistor compared to when no GIDL flows through the second resistor.

Furthermore, when switch 500 is enabled (e.g., placed in an on state so the switch is closed), V_{E} is set to a positive voltage. In this case, the pair of diodes 508 and 512 are reverse-biased, so that they appear as open circuits. As a result, body resistor 510 is removed from being in parallel with bias resistor 506. Body resistor 510 is therefore inhibited from affecting RF performance of the closed switch. Instead, RF performance of the closed switch is governed by bias resistor 506.

In embodiments, the pair of diodes 508 and 512, the pair of resistors 506 and 510, and transistor 502 are fabricated in a same process type and process dimension. For example, pair of diodes 508 and 512, pair of resistors 506 and 510, and transistor 502 can comprise a System-on-Chip (SoC) or application-specific integrated circuit (ASIC). In some embodiments, the switch 500 is implemented using silicon on insulator (Sol) technology.

Having considered a discussion of example switch 500, consider now a discussion of example switch performance data.

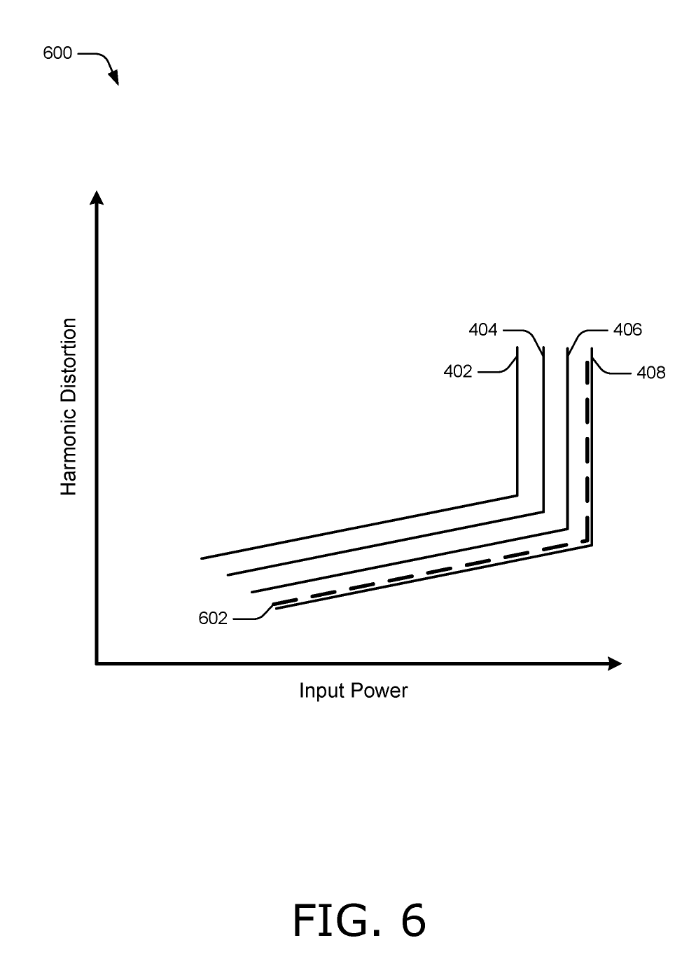

FIG. 6 illustrates example switch performance data 600 in accordance with one or more aspects of the disclosure. Example switch performance data 600 plots harmonic distortion measured at a switch transistor output, versus input power of an input signal to the switch, analogous to example switch performance data 400 in FIG. 4. For instance, switch performance data 600 includes the same family of four curves, 402, 404, 406, and 408 for a transistor as illustrated in FIG. 4.

However, FIG. 6 also includes curve 602, which corresponds to performance of switch 500, including bias circuit 504, at a constant value of V_{E} to negatively bias the gate of transistor 502. Unlike curve 414 in FIG. 4, which corresponds to performance of switch 300, curve 602 in FIG. 6 does not exhibit premature harmonic distortion or a decrease of the breakdown voltage of the transistor. Instead, curve 602 indicates that by using bias circuit 504 that includes a pair of diodes and a pair of parallel resistors, performance of switch 500 matches the expected performance of transistor 502 alone. For instance, curve 602 is not an arc like curve 414 in FIG. 4, but is instead a “hockey-stick” shape like the family of four curves, 402, 404, 406, and 408. Hence, the performance of the switch has been corrected by routing current away from the bias resistor 506 to thereby inhibit a voltage drop on the gate of transistor 502, as discussed above with respect to FIG. 5.

Having considered a discussion of example switch performance data 600, consider now a discussion of example methods for configuring and operating a transistor switch.

Example Procedure

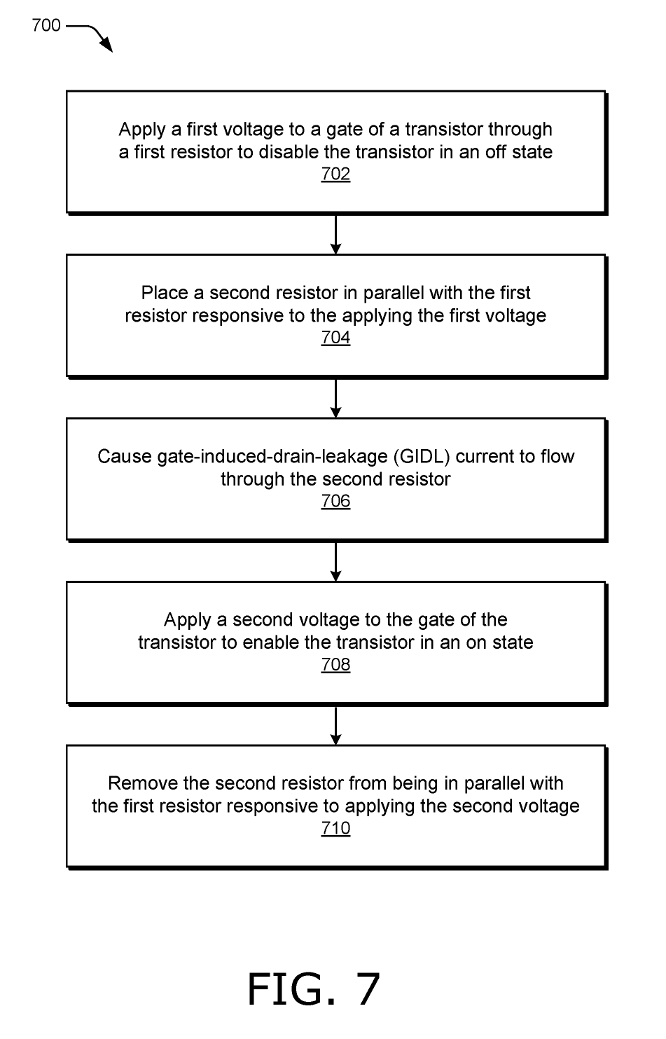

FIG. 7 illustrates an example procedure for configuring and operating a transistor switch 700 in accordance with one or more aspects of the disclosure. Aspects of the procedure may be implemented in hardware, firmware, software, or a combination thereof. The procedure is shown as a set of blocks that specify operations performed by one or more devices and are not necessarily limited to the orders shown for performing the operations by the respective blocks. In at least some embodiments the procedure may be performed by a suitably configured device or devices, such as user device 102 described in FIG. 1 or wireless communication device 200 in FIG. 2.

A first voltage is applied to a gate of a transistor through a first resistor to disable the transistor in an off state (block 702). In embodiments, the first voltage is a negative voltage. The first resistor can be a biasing resistor, and the first voltage is applied using a control voltage, such as from an external voltage source or voltage supply circuit. The transistor is configured as a switch, with an input terminal and an output terminal, and the off state corresponds to the switch being open. In one example, the switch is configured to process RF signals.

A second resistor is placed in parallel with the first resistor responsive to applying the first voltage (block 704). In one example, the second resistor is placed in parallel with the first resistor by forward-biasing a pair of diodes. One of the diodes is configured with an anode connected to a body of the transistor and a cathode connected to the gate of the transistor, and the other of the diodes is configured with an anode connected to the second resistor and a cathode connected to a voltage source used for applying the first voltage.

GIDL current is caused to flow through the second resistor (block 706). A drop in the first voltage on the gate of the transistor is inhibited by flowing the GIDL current. For instance, the first voltage is inhibited from becoming less negative when a negative bias voltage is applied to the gate of the transistor at block 702 and at least part of the GIDL current flows through the second resistor. The second resistor can be smaller than the first resistor, so that more GIDL current flows through the second resistor than flows through the first resistor. In an embodiment, the second resistor has a resistance value that is nominally half the resistance value of the first resistor.

A second voltage is applied to the gate of the transistor to enable the transistor in an on state (block 708). The on state corresponds to the switch being closed. The second voltage can be a positive voltage supplied from an external voltage source, such as a voltage supply circuit on a same chip containing the transistor.

The second resistor is removed from being in parallel with the first resistor responsive to applying the second voltage (710). In one example, the second resistor is removed from being in parallel with the first resistor by reverse-biasing a pair of diodes. By removing the pair of resistors from being in parallel, the second resistor is inhibited from affecting the RF performance of the switch.

Having considered a discussion of example methods for configuring and operating a transistor switch, consider now a discussion of an example device having components through which aspects of configuring and operating a transistor switch can be implemented.

Example Device

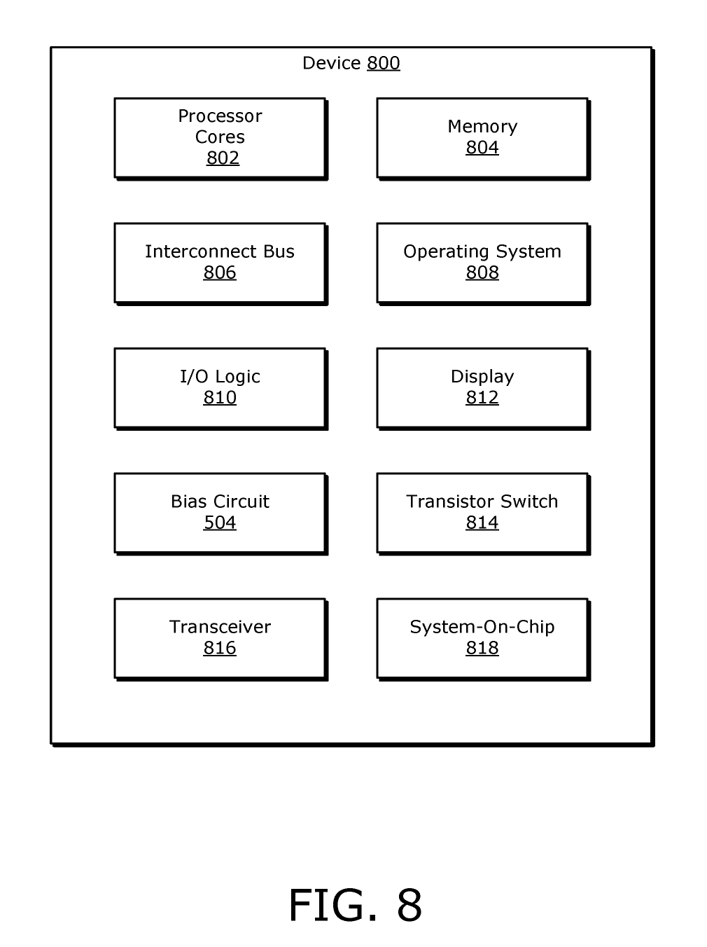

FIG. 8 illustrates an example device 800, which includes components capable of implementing aspects of configuring and operating a transistor switch. Device 800 may be implemented as, or in, any suitable electronic device, such as a modem, broadband router, access point, cellular phone, smart-phone, gaming device, laptop computer, desktop computer, net book, set-top-box, smart-phone, network-attached storage (NAS) device, cell tower, satellite, cable head-end, and/or any other device that may use a transistor switch.

Device 800 may be integrated with a microprocessor, storage media, I/O logic, data interfaces, logic gates, a transmitter, a receiver, circuitry, firmware, software, and/or combinations thereof to provide communicative or processing functionalities. Device 800 may include a data bus 806 (e.g., cross bar or interconnect fabric) enabling communication between the various components of the device. In some aspects, components of device 800 may interact via the data bus to implement aspects of configuring and operating a transistor switch.

In this particular example, device 800 includes processor cores 802 and memory 804. Memory 804 may include any suitable type of memory, such as volatile memory (e.g., DRAM), non-volatile memory (e.g., flash), cache, and the like. In the context of this disclosure, memory 804 is implemented as a storage medium, and does not include transitory propagating signals or carrier waves. Memory 804 can store data and processor-executable instructions of device 800, such as operating system 808 and other applications. Processor cores 802 may execute operating system 808 and other applications from memory 804 to implement functions of device 800, the data of which may be stored to memory 804 for future access. For example, processor cores may switch control signals to configure switches as enabled or disabled. Device 800 may also include I/O logic 810, which can be configured to provide a variety of I/O ports or data interfaces for communication. Device 800 also includes display 812. Display 812 may comprise any suitable type of display, such as a liquid crystal display (LCD), and be configured to provide a user interface on device 800.

Device 800 also includes bias circuit 504. Bias circuit 504 includes at least one pair of diodes and at least one pair of resistors that can be placed in parallel by appropriately biasing the pair of diodes. Transistor switch 814 comprises one or more transistors configured as switches. The transistors can be any suitable type of transistors, such as by way of example and not limitation, MOSFET's. Transistor 110 in FIG. 1 is an example of a transistor configured as a switch.

Device 800 also includes transceiver 816. Transceiver 816 is any suitable type of transceiver, such as a receiver, transmitter, or combinations thereof, and is configurable for communication of one or more types of signals, such as cellular phone signals. Transceiver 816 can use switches from transistor switch 814 that are controlled using bias circuit 504, such as to select between transmit and receive signals in a mobile phone.

Device 800 also includes System-on-Chip (SoC) 818. SoC 818 comprises a variety of functions on a single chip or die, or multiple die in a single package. In embodiments, SoC comprises bias circuit 504 and transistor switch 814.

The term “component”, “module”, and “system” are indented to refer to one or more computer related entities, such as hardware, firmware, software, or any combination thereof, as further described above. At times, a component may refer to a process and/or thread of execution that is defined by processor-executable instructions. Alternately or additionally, a component may refer to various electronic and/or hardware entities.

Certain specific embodiments are described above for instructional purposes. The teachings of this disclosure have general applicability, however, and are not limited to the specific embodiments described above.

What is claimed is:

1. A switch comprising:
a transistor;
a first diode having an anode connected to a body of the transistor and a cathode connected to a gate of the transistor;
a first resistor connected to the gate of the transistor and a voltage; and
a second resistor connected to the body of the transistor and an anode of a second diode, the second diode having a cathode connected to the voltage.

2. The switch as recited in claim 1, wherein the second resistor has a resistance value less than a resistance value of the first resistor.

3. The switch as recited in claim 1, wherein the second resistor has a resistance value that is nominally half a resistance value of the first resistor.

4. The switch as recited in claim 1, wherein the switch is configured such that gate-induced-drain-leakage (GIDL) current, when flowing, flows from the body of the transistor through the first resistor and the second resistor, and more GIDL current flows through the second resistor than flows through the first resistor.

5. The switch as recited in claim 1, wherein the switch is configured such that gate-induced-drain-leakage (GIDL) current, when flowing, flows from the body of the transistor through the first resistor and the second resistor, and GIDL current that flows through the second resistor causes a higher breakdown voltage of the transistor compared to when no GIDL flows through the second resistor.

6. The switch as recited in claim 1, wherein the switch is configured such that gate-induced-drain-leakage (GIDL) current, when flowing, flows from the body of the transistor through the first resistor and the second resistor, and GIDL current that flows through the second resistor causes a lower harmonic distortion of the transistor compared to when no GIDL flows through the second resistor.

7. The switch as recited in claim 1, wherein the second resistor causes a voltage on the gate of the transistor to become more negative when the transistor is in an off state compared to when the second resistor is disconnected from the switch.

8. The switch as recited in claim 1, wherein when the transistor is in an off state, the first resistor and the second resistor are in parallel.

9. The switch as recited in claim 1, wherein the transistor, the first diode, the second diode, the first resistor, and the second resistor are implemented in a System-on-Chip (SoC).

10. The switch as recited in claim 1, wherein the switch is coupled to a source of a radio frequency (RF) signal.

11. The switch as recited in claim 1, wherein the switch is coupled to an output of a power amplifier.

12. The switch as recited in claim 1, wherein the switch is coupled to an antenna and is configured to switch between transmit and receive signals.

13. A method of operating a switch, the method comprising:
applying a first voltage to a gate of a transistor through a first resistor to disable the transistor in an off state;
placing a second resistor in parallel with the first resistor responsive to the applying the first voltage;
causing gate-induced-drain-leakage (GIDL) current to flow through the second resistor;
applying a second voltage to the gate of the transistor to enable the transistor in an on state; and
removing the second resistor from being in parallel with the first resistor responsive to the applying the second voltage.

14. The method as recited in claim 13, wherein the first voltage is negative and the second voltage is positive.

15. The method as recited in claim 13, wherein the second resistor has a resistance value less than a resistance value of the first resistor.

16. The method as recited in claim 13, wherein less GIDL current flows through the first resistor than the second resistor.

17. The method as recited in claim 13, wherein the placing the second resistor comprises forward-biasing a pair of diodes and the removing the second resistor comprises reverse-biasing the pair of diodes.

18. The method as recited in claim 17, wherein one of the diodes is configured with an anode connected to a body of the transistor and a cathode connected to the gate of the transistor, and the other of the diodes is configured with an anode connected to the second resistor and a cathode connected to a voltage source used for the applying the first voltage.

19. The method as recited in claim 13, wherein the causing the GIDL current to flow through the second resistor causes the first voltage to become more negative compared to when no current flows through the second resistor.

20. A device comprising:
means for applying a first voltage to a gate of a transistor through a first resistor to disable the transistor in an off state;
means for placing a second resistor in parallel with the first resistor responsive to the applying the first voltage; and
means for causing gate-induced-drain-leakage (GIDL) current to flow through the second resistor.

21. The device as recited in claim 20, wherein the second resistor has a resistance value less than a resistance value of the first resistor.

22. The device as recited in claim 20, wherein the means for causing the GIDL current to flow comprises means for flowing less GIDL current through the first resistor than the second resistor.

23. The device as recited in claim 20, wherein the means for placing the second resistor comprises means for forward-biasing a pair of diodes.

24. The device as recited in claim 20, further comprising:
means for applying a second voltage to the gate of the transistor to enable the transistor in an on state; and
means for removing the second resistor from being in parallel with the first resistor responsive to the applying the second voltage.

25. The device as recited in claim 24, wherein the means for removing the second resistor comprises means for reverse-biasing a pair of diodes.

26. A system comprising:
a transistor;
a first resistor having a first terminal connected to a gate of the transistor and a second terminal coupled to a voltage input;
a second resistor having a first terminal connected to a body of the transistor and a second terminal coupled to the voltage input; and
a pair of diodes configured to selectively place the first resistor and the second resistor in parallel.

27. The system as recited in claim 26, wherein the pair of diodes are configured to place the first resistor and the second resistor in parallel when the pair of diodes are forward-biased.

28. The system as recited in claim 26, wherein the second resistor has a resistance value less than a resistance value of the first resistor.

29. The system as recited in claim 26, wherein when the transistor is disabled in an off state, gate-induced-drain-leakage (GIDL) current, when flowing, flows from the body of the transistor through the first resistor and the second resistor, and more GIDL current flows through the second resistor than flows through the first resistor.

30. The system as recited in claim 26, wherein the transistor, the first resistor, the second resistor, and the pair of diodes are fabricated in a same process type.
